(19) United States
(12) Patent Application Publication
(10) Pub. No.: US 2025/0220938 A1
(43) Pub. Date: Jul. 3, 2025

(54) SEMICONDUCTOR DEVICE AND POWER CONVERSION DEVICE

(71) Applicant: Minebea Power Semiconductor Device Inc., Ibaraki (JP)

(72) Inventor: Masaki SHIRAISHI, Hitachi-shi (JP)

(21) Appl. No.: 18/841,726

(22) PCT Filed: Dec. 9, 2022
(86) PCT No.: PCT/JP2022/045442

§ 371 Date: Aug. 27, 2024

(30) Foreign Application Priority Data
Mar. 28, 2022 (JP) 2022-051445

(51) Int. Cl. H10D 12/00; H02M 7/537; H10D 8/00; H10D 62/10; H10D 84/80

(52) U.S. Cl. CPC H10D 12/416; H02M 7/537; H10D 8/411; H10D 12/415; H10D 12/481; H10D 62/124; H10D 84/811

(57) ABSTRACT

Provided are a semiconductor device and a power conversion device for improvement in the recovery characteristic by suppressing the hole injection through reduction in the area of the p body layer in the diode unit of the RC-IGBT. A semiconductor device according to the present invention is formed as an RC-IGBT having an IGBT unit and a diode unit formed in a single chip. A collector electrode layer/cathode electrode layer, a diffusion layer, a buffer layer, a drift layer, a body layer, an insulating layer, and an emitter/anode electrode layer are stacked in the order from a back surface side to a front surface side of the chip. The diode unit includes a plurality of trenches. The plurality of trenches 6 include a region in the presence of the body layer between the trenches, and a region in the absence of the body layer between the trenches.

### TECHNICAL FIELD

The present invention relates to a semiconductor device and a power conversion device.

### BACKGROUND ART

A reverse conducting IGBT (hereinafter referred to as “RC-IGBT”) formed by incorporating an IGBT (Insulated Gate Bipolar Transistor) and a diode in the same chip provides advantages: (1) reduction in the chip size by making each termination region of the IGBT and the diode commonized; and (2) reduction in thermal resistance by dissipating the loss generated either in the IGBT region or the diode region from the entire chip. Meanwhile, as the IGBT and the diode are fabricated in the same chip, it is difficult to attain simultaneous optimization among the respective chips. Especially, it is difficult to execute the life-time control of the diode unit, which demands the low injection of the diode, and reduction in the recovery loss.

Patent Literature 1 discloses the technology for the purpose of attaining the low injection of the diode unit of the RC-IGBT, for example. The semiconductor device as disclosed in Patent Literature 1 is structured as described below. A plurality of first grooves 6 are arranged in the region A (IGBT region). Those grooves are arranged at equal first intervals. A plurality of second grooves 10 are formed in the region B (diode region). Those grooves are arranged at equal second intervals. The second interval is set to be smaller than the first interval. In Patent Literature 1, more grooves are formed in the region B (diode region). When the diode becomes the on-state, the area of the P base layer 2 functioning as the anode of the diode is relatively reduced. Accordingly, the hole injection into the P base layer 2 is suppressed to reduce the carrier density of an area around the first main surface. This makes it possible to lower the peak current upon recovery operation, and further to improve the recovery characteristic of the diode.

### CITATION LIST

### Patent Literature

Patent Literature 1: Japanese Unexamined Patent Application Publication No. 2008-53648

### SUMMARY OF INVENTION

### Technical Problem

The technology disclosed in Patent Literature 1 suppresses the hole injection by reducing the area of the P base layer 2 (p body layer) in the diode unit of the RC-IGBT. In the method as disclosed in Patent Literature 1, however, the trench interval is narrowed to reduce the area of the p body layer. Such method restricts the reduction in the area of the p body layer owing to limit of trench processing.

In light of the above circumstances, the present invention provides a semiconductor device and a power conversion device for improvement in the recovery characteristic by suppressing the hole injection through reduction in the area of the p body layer in the diode unit of the RC-IGBT.

### Solution to Problem

According to an aspect of the present invention to solve the above-described problem, a semiconductor device is formed into an RC-IGBT having an IGBT unit and a diode unit formed in a single chip. A collector electrode layer/cathode electrode layer, a diffusion layer, a buffer layer, a drift layer, a body layer, an insulating layer, and an emitter/anode electrode layer are stacked in the order from a back surface side to a front surface side of the chip. The diode unit includes a plurality of trenches. The plurality of trenches include a region in the presence of the body layer between the trenches, and a region in the absence of the body layer between the trenches.

According to another aspect of the present invention to solve the above-described problem, a power conversion device includes a pair of DC terminals, AC terminals, the number of which is the same as the number of phases of an AC output, switching legs that are connected between the pair of DC terminals, the number of which is the same as the number of phases of the AC output, and connected in series to two parallel circuits each formed of a switching element and a diode connected reversely in parallel to the switching element, and a gate circuit for controlling the switching element. The diode and the switching element constitute the above-described semiconductor device.

The specific structure of the present invention is described in claims.

### Advantageous Effects of Invention

The present invention provides the semiconductor device and the power conversion device for improvement in the recovery characteristic by suppressing the hole injection through reduction in the area of the p body layer in the diode unit of the RC-IGBT.

Other problems, structures, and advantageous effects will be clarified by explanations of an embodiment as described below.

### BRIEF DESCRIPTION OF DRAWINGS

FIG. 1 is a sectional view schematically showing a first example of a semiconductor device according to the present invention.

FIG. 2 is a sectional view schematically showing a second example of a semiconductor device according to the present invention.

FIG. 3 is a circuit diagram schematically showing a structure of a power conversion device according to the present invention.

### DESCRIPTION OF EMBODIMENTS

The present invention is described in detail with reference to the drawings.

### [Semiconductor Device]

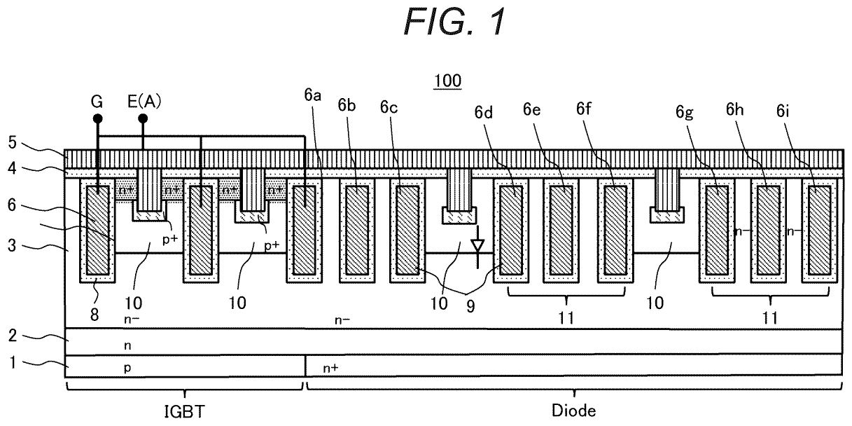

FIG. 1 is a sectional view schematically showing a first example of a semiconductor device according to the present invention. As FIG. 1 shows, a semiconductor device (RC-IGBT) 100 according to the present invention includes an IGBT unit and a diode unit. The semiconductor device is structured by stacking connected to a collector electrode layer/cathode electrode layer (not shown), a diffusion layer 1, a buffer layer 2, an n-drift layer 3 and a p body layer 10, an insulating layer 4, and an emitter anode electrode 5 from a back surface side to the front surface side. The conductive type “p” and conductive type “n” as shown in FIG. 1 may be inverted.

The IGBT unit has its front surface side structured to have a gate electrode G, an emitter/anode electrode E (A), and a trench (gate trench) 6, which are electrically connected to one another. The trench 6 is covered with an oxide film 8. The p body layer 10 is formed between the trenches 6. A trench 9 may be formed as an emitter.

The diode unit has its front surface side structured to have a region 11 in the absence of the p body layer 10 (p body layer 10 is removed) between the specific trenches 6. In the region 11 in the absence of the p body layer, the interval between the trenches 6 is narrower than the interval between the trenches of the region in the presence of the p body layer 10. Specifically, each interval among the trenches 6a to 6c, 6d to 6f, and 6g to 6i is narrower than each interval between the trenches 6c and 6d, and between the trenches 6f and 6g. By narrowing the interval between the trenches, the n-layer between the trenches 6 is depleted to secure pressure resistance.

The above-described structure allows reduction in the area of the p body layer in the diode unit, thus attaining the low injection of the diode. This makes it possible to improve the recovery characteristic of the semiconductor device 100.

FIG. 1 shows that the ratio between the region in the presence of the p body layer and the region in the absence of the p body layer is 1:1. Such ratio, however, may be arbitrarily changed. The area of the p body layer may be arbitrarily set to adjust the trade-off between the forward voltage and the recovery loss of the diode. For example, the area of the body layer 10 may be set to be 50% of an area of the cathode electrode layer or smaller in the planar view of the diode unit. This attains the low injection of the diode.

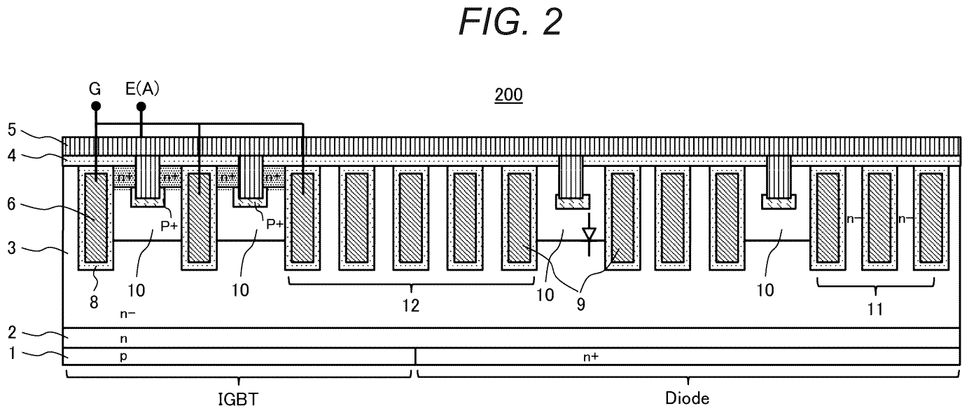

FIG. 2 is a sectional view schematically showing a second example of a semiconductor device according to the present invention. A semiconductor device 200 shown in FIG. 2 is formed by adding a region 12 where a plurality of trenches 6 are formed in the absence of the p body layer 10 at the boundary between the IGBT unit and the diode unit to the structure of the semiconductor device 100 as shown in FIG. 1. In the case of the RC-IGBT, upon recovery of the diode, the hole flows into an area of the IGBT at the boundary with respect to the diode unit. This may cause the risk of destruction of the semiconductor device 200 at the boundary. The semiconductor device 200 as shown in FIG. 2 has a plurality of trenches 6 in the absence of the p body layer 10 at the boundary between the diode unit and the IGBT unit to increase the distance between ends of the diode unit and the IGBT unit. This makes it possible to prevent the hole from flowing into the area of the IGBT at the boundary with respect to the diode unit as described above, thus restraining destruction of the semiconductor device 200. The p body layer 10 is not formed between the trenches at the boundary to ensure suppression of the hole injection from the p body layer 10.

### [Power Conversion Device]

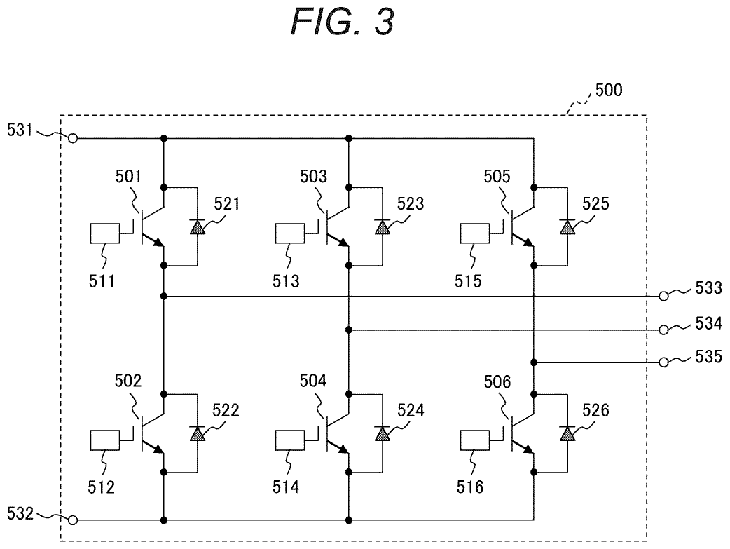

FIG. 3 is a circuit diagram schematically showing a structure of the power conversion device according to the present invention. FIG. 3 shows an example of a circuit structure of a power conversion device 500 of an embodiment, and a connection relation between a DC power supply and a three-phase AC motor (AC load).

The power conversion device 500 of the embodiment employs the semiconductor devices according to the present invention as elements 501 to 506, and 521 to 526.

As FIG. 3 shows, the power conversion device 500 of the embodiment includes a pair of DC terminals constituted by a P terminal 531 and an N terminal 532, and a U terminal 533, a V terminal 534, and a W terminal 535 as AC terminals, the number of which is the same as the number of AC output phases.

The power conversion device includes a switching leg formed of a pair of power switching elements 501 and 502 connected in series, and makes the U terminal 533 connected to a series connected point of those elements serving as an output. The power conversion device further includes a similarly structured switching leg formed of a pair of power switching elements 503 and 504 connected in series, and makes the V terminal 534 connected to a series connected point of those elements serving as an output. The power conversion device further includes a similarly structured switching leg formed of a pair of power switching elements 505 and 506 connected in series, and makes the W terminal 535 connected to a series connected point of those elements serving as an output.

The three-phase switching legs which are formed of the power switching elements 501 to 506, respectively are connected between the DC terminals of the P terminal 531 and the N terminal 532 so that DC power is supplied from a not shown DC power supply. The three-phase AC terminals including the U terminal 533, the V terminal 534, and the W terminal 535 of the power conversion device 500 are connected to a not shown three-phase AC motor while serving as a three-phase AC power supply.

The power switching elements 501 to 506 are connected reversely in parallel to the diodes 521 to 526, respectively. Input terminals of the respective gates of the power switching elements 501 to 506 each formed of the IGBT, for example, are connected to gate circuits 511 to 516 correspondingly so that the power switching elements 501 to 506 are controlled by the gate circuits 511 to 516, respectively. The gate circuits 511 to 516 are integrally controlled by an integrated control circuit (not shown).

The gate circuits 511 to 516 execute integral control of the power switching elements 501 to 506 appropriately so that the DC power of a DC power supply Vcc is converted into the three-phase AC power, and the converted power is output from the U terminal 533, the V terminal 534, and the W terminal 535.

Application of the semiconductor device (RC-IGBT) according to the present invention to the power conversion device 500 allows integration of the power switching elements 501 to 506, and the diodes 521 to 526 into a single structure, resulting in size reduction of the device. As described above, the use of the semiconductor device according to the present invention allows provision of the power conversion device which improves the recovery characteristic of the diode unit.

The present invention shows that it is possible to provide the semiconductor device and the power conversion device for improvement in the recovery characteristic by suppressing the hole injection through reduction in the area of the p body layer in the diode unit of the RC-IGBT. The present invention is not limited to the above-described embodiment, but includes various modifications.

For example, the aforementioned embodiment has been described in detail for easy understanding of the present invention. Therefore, it is not necessarily limited to be configured to have all the structures as described above.

### REFERENCE SIGNS LIST

1: diffusion layer, 2: buffer layer, 3: drift layer, 4: insulating layer, 5: emitter/anode electrode, 6, 6a, 6b, 6c, 6d, 6e, 6f, 6h, 6i: trench, 10: p body layer, 11, 12: region in absence of p body layer, 100, 200: semiconductor device, 500: power conversion device, 501 to 506: power switching element, 511 to 516: gate circuit, 521 to 526: diode, 531: P terminal, 532: N terminal, 533: U terminal, 534: V terminal, 535: W terminal

1. A semiconductor device comprising an RC-IGBT having an IGBT unit and a diode unit formed in a single chip, wherein:
a collector electrode layer/cathode electrode layer, a diffusion layer, a buffer layer, a drift layer, a body layer, an insulating layer, and an emitter/anode electrode layer are stacked in the order from a back surface side to a front surface side of the chip;
the diode unit includes a plurality of trenches; and
the plurality of trenches include a region in the presence of the body layer between the trenches, and a region in the absence of the body layer between the trenches.

2. The semiconductor device according to claim 1, wherein an interval between the trenches in the region in the absence of the body layer is narrower than an interval between the trenches in the region in the presence of the body layer.

3. The semiconductor device according to claim 1, wherein an area of the body layer is 50% of an area of the cathode electrode layer or smaller in a planar view of the diode unit.

4. The semiconductor device according to claim 1, wherein the plurality of trenches in the region in the absence of the body layer are arranged at a boundary between the IGBT unit and the diode unit.

5. A power conversion device including:
a pair of DC terminals;
AC terminals, the number of which is the same as the number of phases of an AC output;
switching legs, the number of which is the same as the number of phases of the AC output, the switching leg being connected between the pair of DC terminals, and the switching leg including two parallel circuits connected in series, and each of the two parallel circuits being formed of a switching element and a diode connected reversely in parallel to the switching element; and
a gate circuit for controlling the switching element,
wherein the diode and the switching element constitute the semiconductor device according to claim 1.
